(19) United States
(12) Patent Application Publication
(10) Pub. No.: US 2013/0263920 A1
(43) Pub. Date: Oct. 10, 2013

(54) MULTI-JUNCTION SOLAR CELLS WITH THROUGH-VIA CONTACTS

(71) Applicant: SOLAR JUNCTION CORPORATION, SAN JOSE, CA (US)

(72) Inventors: ONUR FIDANER, SAN JOSE, CA (US); MICHAEL WEST WIEMER, CAMPBELL, CA (US)

(73) Assignee: SOLAR JUNCTION CORPORATION, SAN JOSE, CA (US)

(21) Appl. No.: 13/856,573

(22) Filed: Apr. 4, 2013

Related U.S. Application Data
(60) Provisional application No. 61/621,277, filed on Apr. 6, 2012.

(51) Int. Cl. H01L 31/0224

(52) U.S. Cl. CPC H01L 31/022441
USPC 136/255

(57) ABSTRACT

Multi junction solar cell devices are provided in which through-wafer vias contacting the top surface eliminate the need for gridlines and enhance efficiency of epitaxially grown multi junction solar cell elements.

This application claims the benefit under 35 U.S.C. §119(e) of U.S. Provisional Application No. 61/621,277 filed on Apr. 6, 2012, which is incorporated by reference in its entirety.

### BACKGROUND OF THE INVENTION

This invention relates to multi junction solar cells and methods for making thereof. More particularly the invention relates to metal electrodes on the front surface of multi-junction solar cells, wherein the front side faces the sun.

Conventional multi junction solar cells have been widely used for terrestrial and space applications. Multi-junction solar cells, typically considered as high-powered solar cells, comprise multiple diodes (aka junctions) in series connection, realized by growing thin regions of epitaxy in stacks on semiconductor substrates. Each junction in a stack is optimized for absorbing a different portion of the solar spectrum, thereby improving efficiency of solar energy conversion.

Conventional multi junction solar cells have features that reduce the efficiency of solar to electrical energy conversion. For example, a portion of solar energy incident on the front side of a solar cell cannot be absorbed due to metallic electrodes blocking a portion of the side facing the sun. Furthermore a portion of the absorbed solar energy cannot be collected at the electrodes as electrical power since it is dissipated as heat (for example, resistive loss) during lateral conduction in the emitter region of the top junction and in the metallic gridlines. For high-power devices, such as concentrated photovoltaic devices or large area solar cells, the dissipated heat may also result in substantially increased temperature, thereby further reducing the performance of the device. Typically there is a trade-off between said parameters and others. Multi-junction solar cells are typically designed to give the optimum solar to electrical energy conversion performance under desired conditions. It is desirable to improve efficiency in multi junction solar cell devices.

FIG. 1A shows the cross-section schematic of a typical (prior art) multi junction solar cell device 100. The solar cell 100 shown in FIG. 1A consists of three sub-cells (junctions) 106-108 that are connected through tunnel junctions 167 and 178. It is to be understood that FIG. 1A is merely an example of a typical multi-junction solar cell and that such solar cells may comprise any number of sub-cells. FIG. 1B is a simplified schematic of a typical (prior art) multi junction solar cell.

Referring to FIG. 1A, the front surface field (FSF) region 4 is the window region that faces the sun after cap etch. Underneath the FSF region 4 is the emitter region 102 of the top p-n junction 106 that forms a diode. Similar junctions 107 and 108 are disposed below the top p-n junction thus forming a multi junction solar cell. The top electrode includes gridlines 2 making contact with the FSF region 4 through cap region 3, wherein the cap region consists of semiconductor material patterned according to the shape of the metallic gridlines 2. The bottom electrode is a metal region 52 at the back surface of the solar cell in contact with the substrate 5.

Of the factors reducing the efficiency of multi junction solar cells, shadowing loss, emitter loss, and grid loss are relevant to the present invention.

Shadowing Loss: In typical multi junction solar cells the top electrode consists of regular grids of metal wires. The metal gridlines 2 and cap regions 3 block sunlight from entering the solar cell. For solar cells for which the width of the cap region is slightly larger than the width of the metal gridlines, the cap width x determines the total width blocking the light for each gridline. The gridline width x′ is typically related to the cap width x through a process constant x_{c}, such that x=x′+x_{c}. Hence, when the shadowing width x is increased or decreased as a design parameter, the metal width x′ is also increased or decreased by the same amount. For gridlines spaced by a distance y, the shadowing loss is approximately x/y. Henceforth, increasing the width x and/or decreasing the spacing y increase the shadowing loss.

Emitter Loss: Carriers are generated all across the cell as a result of absorption of sunlight. Referring to FIG. 2B, photogenerated carriers that reach the emitter 102 have to move laterally toward the gridlines, as illustrated with arrows 28. The emitter 102 and the FSF 3 are thin, doped semiconductor regions and together form a lateral conduction region 132. Carrier transport across the lateral conduction region results in a resistive power loss that depends on the sheet resistivity of the region and the distance the carriers have to travel to reach the gridlines. Hence, for a given sheet resistivity, the smaller the gridline spacing y the smaller the emitter loss is.

Grid Loss: Gridlines are metal resistors, resulting in resistive losses as the current moves toward the busbars, as illustrated with arrows 27. The grid loss is determined by the cross section area and the length of the gridlines and metal resistivity. For larger cells the gridlines are longer, resulting in larger [grid loss]/[total loss] ratio compared to smaller cells. The emitter and grid losses are resistive losses (aka I²R losses). Hence, when the concentration increases, the current extracted from the solar cell increases and consequently the I²R losses increase even more. For example, going from a concentration of 500-times to 1,000-times the resistive losses will approximately quadruple for a given cell design.

The grid loss can be made smaller by using more gridlines (hence reducing y) or increasing the cross-section area (hence increasing x). Hence, reducing the grid loss (for given process parameters) comes at the expense of increased shadowing loss. In prior art solar cells there is a need to reduce grid loss component without increasing the shadowing loss component.

A through wafer via (TWV) is an electrical interconnect between the top (front) and bottom (back) surfaces of a semiconductor chip. TWV structures have been routinely used for a variety of applications in the field of semiconductor devices. Fabrication methods to provide TWV structures are known to the skilled in the art of semiconductor devices. For example, Chen et al. (Journal of Vacuum Science and Technology B, Volume 27, Issue 5, “Cu-plated through-wafer vias for AlGaN/GaN high electron mobility transistors on Si”) disclose a semiconductor device with through wafer vias for a high mobility electron transport device application.

Through wafer via structures have also been applied to solar cell devices. One of the purposes of using TWV structures in solar cells is to provide a back-contact-only solar cell for packaging requirements. Some approaches for back-contact solar cells have been summarized by Van Kerschaver et al. (Progress in Photovoltaics: Research and Applications 2006; 14:107-123).

Kinoshita et al. (US 2008/0276981 A1) disclose a structure that provides a through-wafer-via structure incorporating metal with dielectric liner that connects the gridlines on the top surface to the backside of a solar cell. The structure disclosed by Kinoshita provides a back-contact-only solar cell. However the disclosed structure does not reduce grid losses substantially, since gridlines along the length of the cell are used for current transport.

Dill et al. (U.S. Pat. No. 4,838,952 A) disclose a through-wafer-via structure that connects the emitter region of a solar cell to the backside. The structure disclosed by Dill et al. is not applicable to multi junction solar cells. Multi junction solar cells have a number of epitaxial semiconductor layers with a variety of doping schemas. Henceforth, for multi junction solar cells, it is not possible to use a single doping type around a through-wafer metallic region to electrically isolate it from the semiconductor materials the metallic region is passing through.

Guha et al. (U.S. Pat. No. 8,115,097 B2) disclose a gridline-free contact for a photovoltaic cell. The structure disclosed by Guha et al. employs laterally-insulated through-wafer vias connecting the surface portion of the photovoltaic cell (i.e. the emitter) to the back surface. Contact between the top surface of the metal in the through wafer via and the emitter region is within the substrate, such that there is a region of semiconductor between the top of the through wafer via and the top surface of the solar cell. The disclosure by Guha et al. does not teach how a though-wafer via structure can be integrated in multi junction solar cells, which employ various thin semiconductor epitaxial layers with different purposes. For example, it is a requirement in multi junction solar cells to use a contact region 3 and a front surface field 4 between the emitter 102 and the metal contact 2.

Henceforth, there is a need to increase the efficiency of multi junction solar cells by reducing the grid losses.

### SUMMARY

According to the present invention, a multi junction solar cell is provided that employs through-wafer vias to reduce losses associated with metal grid resistance. In particular, through-wafer vias are provided that are electrically isolated from the solar cell substrate and all the epitaxial regions thereon, except for the cap regions. The cap regions are patterned such that they encircle the via structures on the top surface of the solar cell. In this solar cell scheme, the optimum design is based on trading off shadowing loss, grid resistance loss, and emitter resistance loss, among other factors. The gridlines extending across the entire length of the solar cell are eliminated and both electrodes are accessible from the backside of the multi junction solar cell.

The present invention circumvents these design trade-offs, resulting in different solar cell performance characteristics. For example, an aspect of the present invention is that cell area no longer determines the concentration at which the efficiency peaks. Small cells and large cells will have identical efficiency vs. concentration curves enabling new cost tradeoffs in concentrated photovoltaic system design. FIG. 2C shows a simulation comparing prior art solar cells and solar cells according to the present invention. In prior art solar cells, as the cell size increases, the solar cell efficiency drops due to the design trade-offs. However, the solar cells of the present invention show efficiency characteristics that do not depend on the cell size. Consequently, higher efficiency devices can be made using designs and methods of the present invention.

The semiconductor materials used in the substrate may include, but are not limited to, gallium arsenide and germanium. The epitaxial regions may include one or more lattice matched or metamorphic subcells including, for example tunnel junctions, front surface field (FSF), emitter, depletion region, base and back surface field. Semiconductor materials used in these subcells may include, but are not limited to, indium gallium phosphide, indium phosphide, gallium arsenide, aluminum gallium arsenide, indium gallium arsenide, germanium, and dilute nitride compounds such as GaInNAsSb, GaInNAsBi, GaInNAsSbBi, GaNAsSb, GaNAsBi, and GaNAsSbBi. For ternary and quaternary compound semiconductors, a wide range of alloy ratios can be used.

In a first aspect, multi junction solar cell are provided, comprising: an electrically conductive semiconductor substrate with at least one multi junction solar cell element formed in an epitaxial region grown thereon; a cap region formed on top of the epitaxial region; though-wafer vias that extend from the cap region to a back surface of the substrate; the cap region being shaped according to a cap pattern comprising collars around the through-wafer vias; conductive metal within the through-wafer vias and electrically connected to the collars; an electrically insulating liner on the inner walls of the through-wafer vias insulating the substrate and the epitaxial region from the conductive metal inside the through-wafer vias that connect with the cap region; and a back metal in ohmic contact with the back surface of the substrate, the back metal being electrically connected with the conductive metal within the through-wafer vias, and wherein the back metal is patterned with a back metal pattern.

In a second aspect, multi junction solar cells are provided, comprising: a semi-insulating semiconductor substrate having a top surface and a back surface; an epitaxial region overlying the top surface of the substrate; an electrically conductive semiconductor region between the top surface of the substrate and the epitaxial region; at least one multi-junction solar cell element formed in the epitaxial region; a cap region formed overlying the epitaxial region; though-wafer vias that extend from the cap region to the back surface of the substrate; the cap region being shaped according to a cap pattern comprising a collar around each of the through-wafer vias; conductive metal within each of the through-wafer vias and electrically connected to the respective collar; an electrically insulating liner on the inner walls of each of the through-wafer vias insulating the conductive metal within each of the through-wafer vias from at least the epitaxial region and the electrically conductive semiconductor region; and a back metal in electrical contact with the conductive metal in each of the through-wafer vias.

In a third aspect, multi junction solar cells are provided, comprising: a substrate comprising a lower surface and an upper surface, wherein the upper surface faces the direction of incident radiation; an epitaxial region overlying the upper surface of the substrate, wherein the epitaxial region comprises at least one sub-cell and an upper epitaxial surface; a back metal contact disposed on the lower surface of the substrate; and a plurality of through-vias extending from an annular cap region overlying the upper epitaxial surface to the back metal contact, wherein each of the plurality of through-vias comprises a dielectric liner on the walls of the through-via and an electrically conductive material within a central portion of the through-via; wherein the annular cap region, the electrically conductive material within the central portion of a through-via, and the back metal contact are electrically connected.

In the following description reference is made to the accompanying drawings which form a part hereof wherein like numerals designate like parts throughout, and in which is shown by way of illustration specific embodiments in which the invention may be practiced.

### BRIEF DESCRIPTION OF THE DRAWINGS

FIG. 1A is a cross-sectional diagram of a multi junction solar cell in which the invention could be used.

FIG. 1B is a simplified version of FIG. 1A.

FIG. 2A shows a prior art solar cell with gridlines 2 and busbars 22.

FIG. 2B shows where the grid losses and emitter losses occur.

FIG. 2C is a graph showing the efficiencies of prior art solar cells (in solid lines) and solar cells according to certain embodiments of the present disclosure (in dotted lines).

FIG. 3A is a cross-sectional diagram of through-via contacts formed in accordance with the invention.

FIG. 3B is a top plan view of through-via contacts formed in accordance with the invention.

FIG. 3C is a cross-sectional diagram of through-via contacts formed in accordance with the invention showing at least partial central voids.

FIG. 4A is a cross-sectional diagram of through-via contacts illustrating current flow direction.

FIG. 4B is a top plan view of FIG. 4A illustrating current flow direction.

FIGS. 5A-5H illustrate process steps for forming through-vias according to embodiments of the invention.

FIG. 6A is a side cross-sectional view of through-via contacts in accordance with a further embodiment of the invention.

FIG. 6B is a back surface plan view of FIG. 6A according to one layout.

FIG. 6C is a back surface plan view according to a further layout.

FIG. 7 is a side cross-sectional view according to certain embodiments.

FIGS. 8A-8I illustrate process steps suitable for forming the embodiment of FIG. 7.

FIG. 9A is a side cross-sectional view of through-via contacts in accordance with certain embodiments of the invention.

FIG. 9B is a top plan view of FIG. 9A according to one layout.

FIG. 10 is a side cross-sectional view of through-via contacts in accordance with certain embodiments of the invention.

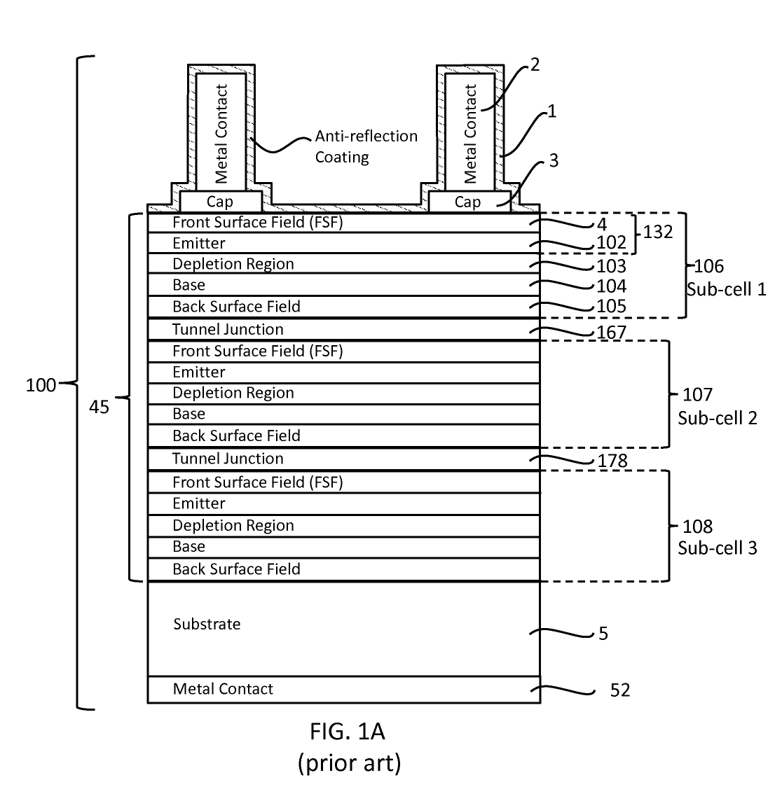

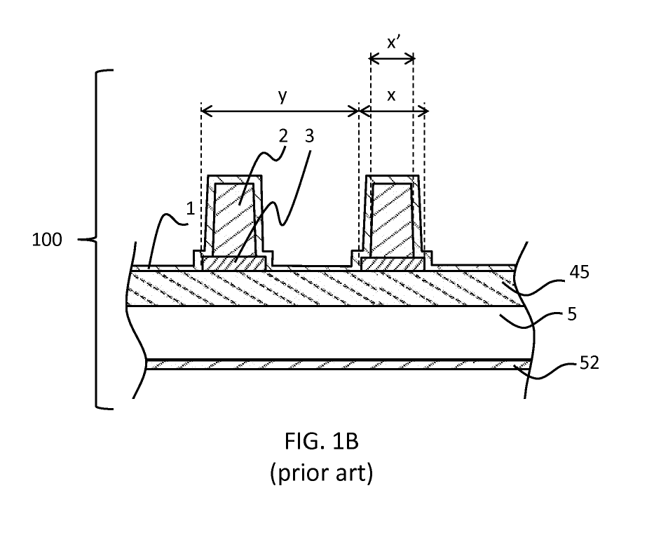

### DETAILED DESCRIPTION OF THE INVENTION

The invention provides a multi junction solar cell device that has modified top and bottom electrode structures compared to prior art solar cells. The modified top electrode structure eliminates current flowing through long gridlines and associated resistive losses. In a multi junction solar cell of the present invention the carriers collected at the emitter region of the top junction generate a current through the lateral conduction region toward the cap regions encircling the via locations. Thereafter, metallic interconnects inside the through vias transport the current to the back surface of the solar cell. This characteristic is explained as follows in connection with the noted figures.

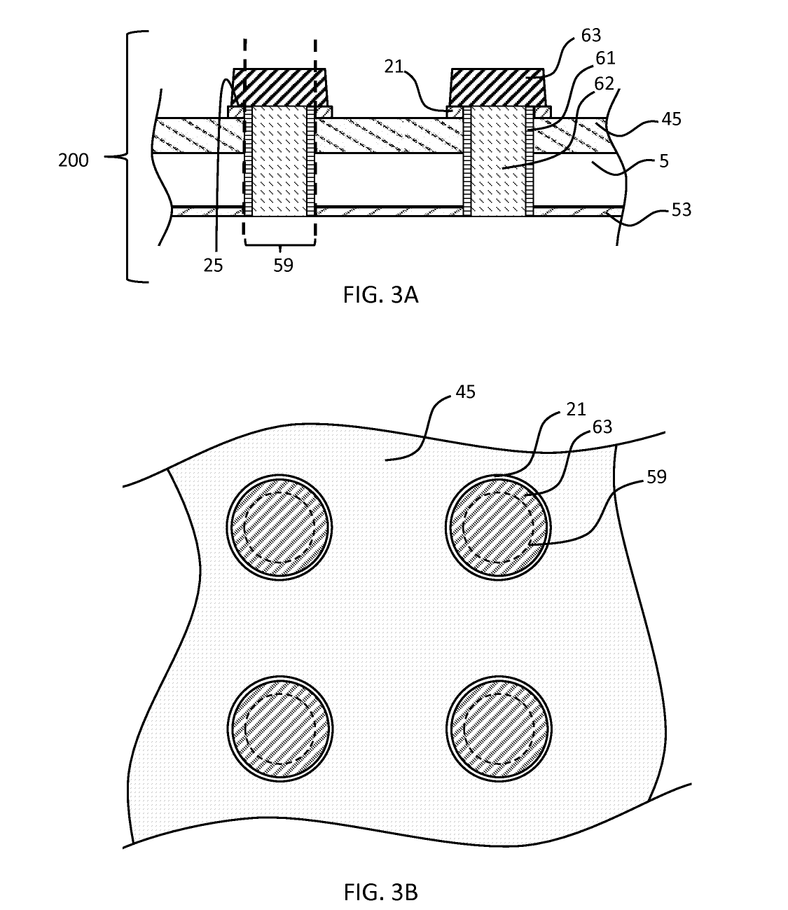

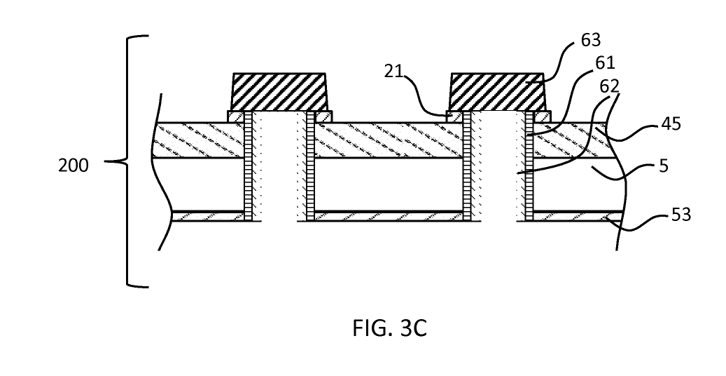

FIGS. 3A and 3B show a specific embodiment of the present invention. The solar cell 200 shown in FIG. 3A comprises junction regions 45 grown on a semiconductor substrate 5. The cap region 21 is patterned in the form of a circular ring and a via structure 59 is formed within that circular ring. The via structure 59 comprises an insulating liner 61 and cylindrical metallic filling 62 and runs through the cap region 21, the junction region 45, and the substrate 5 and back surface metal 53. The metallic filling 62 may be solid like a “plug”, or may be a coating on the insulating liner thus forming a center void running along the length of the via, or some portion of the via length. In other words, the metallic filling 62 may fill the via, or simply coat the sidewalls of the via without filling the via entirely, so long as there is a conductive path the length of the via, as shown in FIG. 3C. The insulating liner 61 provides electrical isolation between the metallic filling 62 and all the non-electrically-insulating semiconductor regions the via passes through. Metallic region 63 electrically connects the metallic via 62 to the top side of the cap region 21 encircling the via structure 59. The semiconductor-metal interface 25 between the cap region 21 and the metallic region 63 is ohmic and provides a low-resistance path for the current flow between the metallic region 63 and the junction region 45. In certain embodiments, the height of metallic region 63 is from 10 nanometer to 100 nanometer above the upper surface of the cap layer 21, with a sheet resistance from 0.1 ohms/square to 5 ohms/square, and in certain embodiments, the height of the metallic region 63 is from 100 nanometer to 10,000 nanometer above the upper surface of the cap layer 21, with a sheet resistance from 0.001 ohms/square to 0.1 ohms/square. In certain embodiments the height of the metallic region is from 20 nanometers to 80 nanometers, from 40 nanometers to 60 nanometers, and in certain embodiments from 10 nanometers to 50 nanometers above the upper surface of the cap layer. In certain embodiments, metallic region 63 has a sheet resistance from 0.1 ohm/square to 2 ohm/square, from 0.1 ohm/square to 1 ohm/square, and in certain embodiments, from 1 ohm/square to 5 ohm/square. In certain embodiments, the height of metallic layer 63 above the upper surface of cap layer 21 is from 500 nanometers to 5,000 nanometers, from 1,000 nanometers to 4,000 nanometers, and in certain embodiments, from 100 nanometers to 1,000 nanometers. In certain embodiments, the sheet resistance of the metallic region is from 0.01 ohms/square to 0.1 ohms/square and in certain embodiments from 0.001 ohms/square to 0.01 ohms/square.

FIG. 3B shows a top plan view of the solar cell of FIG. 3A and illustrates annular cap region 21 and annular metallic region 63, with central via structure 59 disposed on junction region 45. In certain embodiments, the center-to-center distance between adjacent vias is from about 100 microns to about 200 microns, from about 100 microns to about 150 microns, from about 150 microns to about 200 microns, and in certain embodiments, from about 125 microns to about 175 microns. The vias may be arranged in an appropriate configuration to optimize the performance of the solar cell.

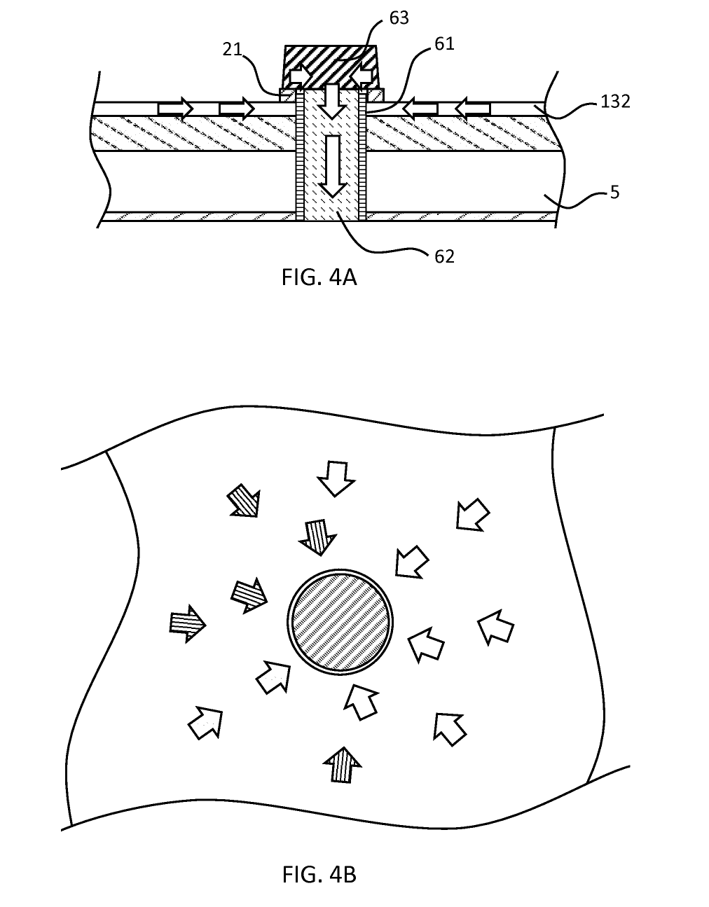

FIGS. 4A and 4B show the current flow direction during normal operation of the device. The current flows laterally through the lateral conduction region 132 on the front surface of the solar cell toward cap region 21. This current flow results in emitter losses. Thereafter, the current flows through the cap region 21, semiconductor-metal interface 25, metal region 63, and metallic filling 62 to reach the back surface of the solar cell device. The diameter of the vias and the total number of vias used in the structure determine the shadowing loss. The distance between the vias and their pattern determine the emitter loss. The diameter of the vias, or more precisely, the cross-sectional area of metal within the via, also determines the resistive losses as current flows through the substrate. With appropriate design parameters the resistive losses in the through-wafer via structures can be made much smaller compared to gridline losses in a prior art solar cell. In addition, it may also be possible to reduce shadowing loss and emitter loss with the present invention. The circular shape of the vias is not to be taken in a limiting sense. It is to be understood that the shape of the vias can be, for example, square, rectangular, or other shapes.

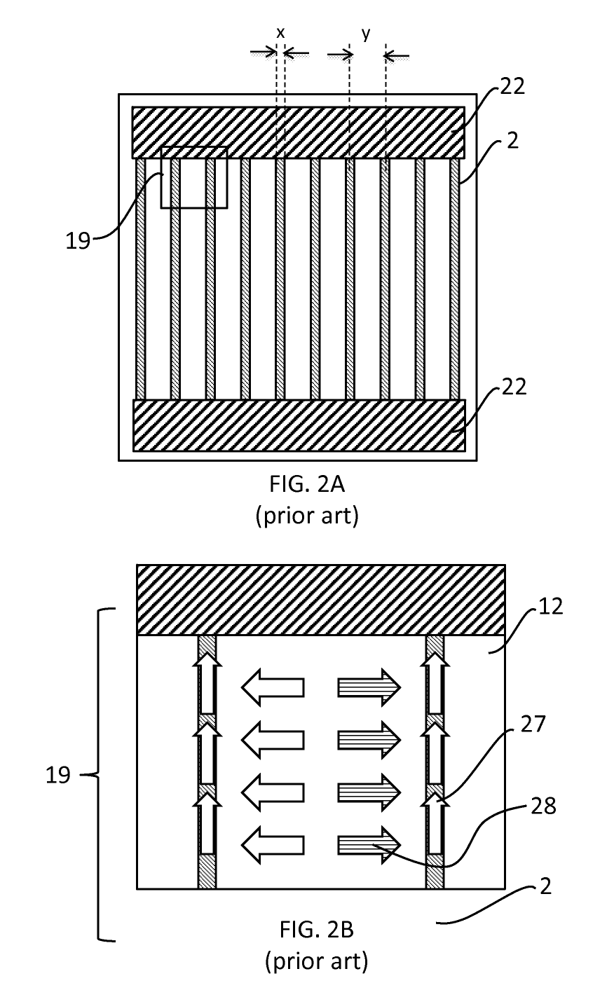

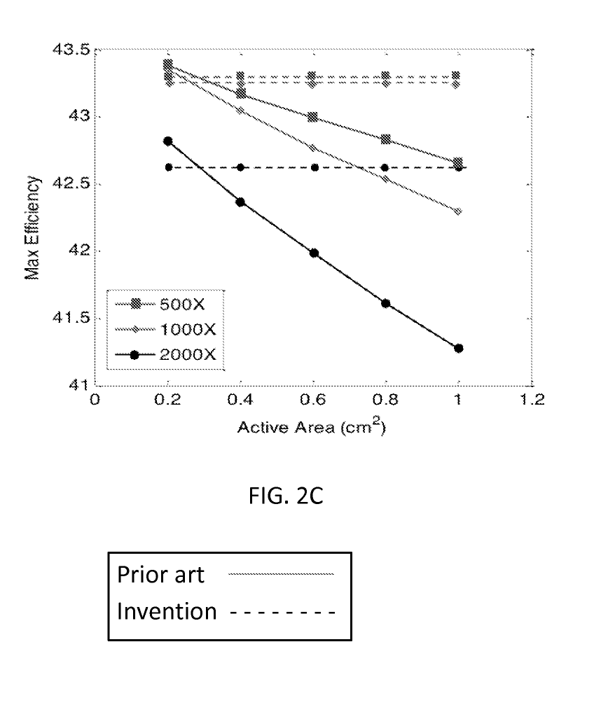

The present invention eliminates the need for busbars on multi junction solar cells by providing a back-contact only device. In prior art solar cells, the area covered by busbars 22 (FIG. 2A) cannot be used for solar energy absorption. The solar cell chip size of the present invention can be made substantially smaller compared to prior art multi junction solar cells since busbars are not needed. Consequently, the present invention may substantially increase the number of solar cell chips yielded per semiconductor wafer. Since the manufacturing costs are typically determined per wafer, the present invention may reduce the manufacturing cost of multi junction solar cells. In certain embodiments, the busbars and the gridlines do not contain silver metal.

In prior art solar cells, silver, a high-conductivity metal, is typically used to form the busbars 22 and gridlines 2. Furthermore the metal grids typically need to be sufficiently thick to provide a larger cross-section area. The present invention substantially reduces metallic resistance losses since the prior art structures are not employed. Moreover, since multi-junction solar cells of the present invention can be made without using silver, manufacturing costs can be further reduced.

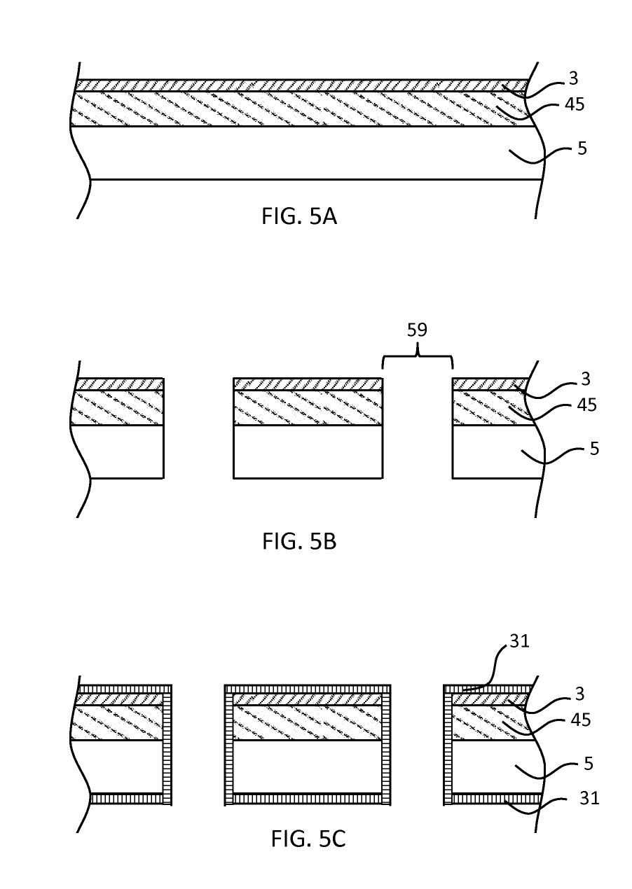

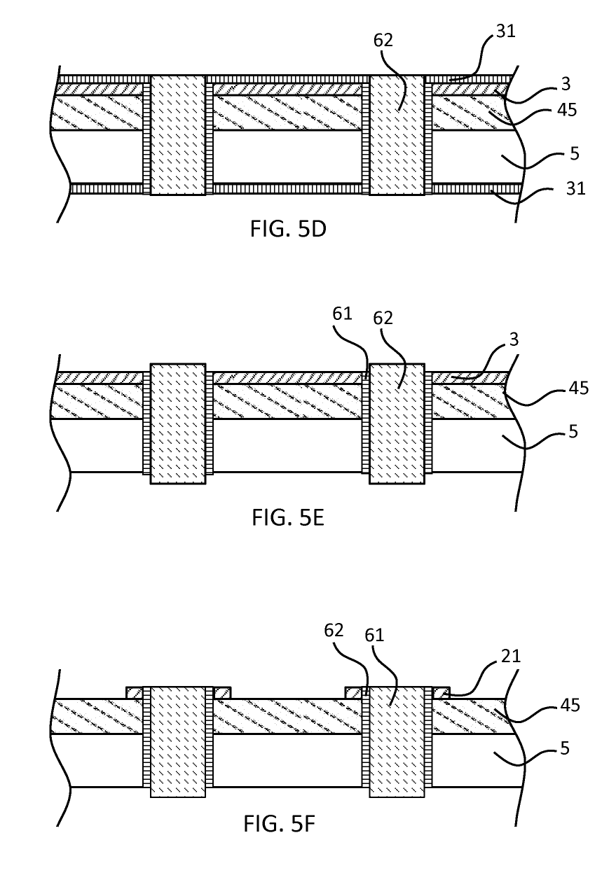

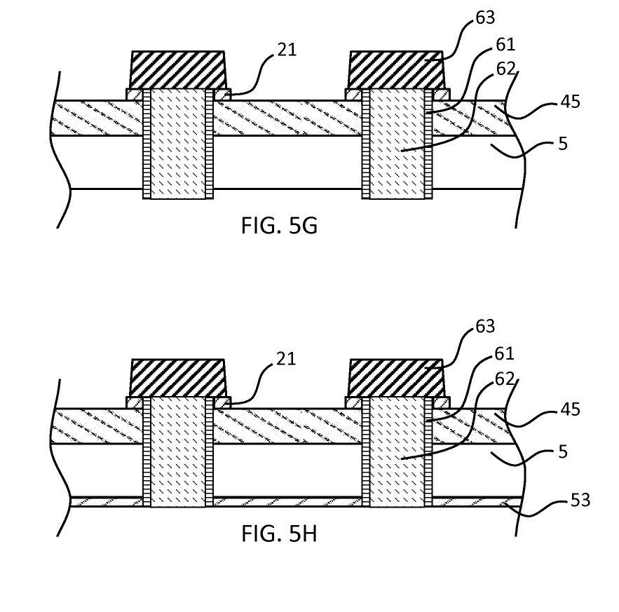

FIGS. 5A-5H show exemplary process steps for making a device according to certain embodiments of the present invention. A cross section showing two via sites is illustrated. The fabrication steps provided herein are merely for illustration and are not meant to limit the scope of the invention. For example, the same structure, as depicted in FIG. 5H, may be obtained by performing a backside process, in which the via holes are etched from the backside of the device. Suitable process steps for fabricating devices provided by the present disclosure include, for example:
1. FIG. 5A: Provide a semiconductor substrate 5 with epitaxial regions 45 such that the top portion is a metallic cap region 3 formed of a semiconductor and underneath is a protected and uncontaminated window region within the epitaxial regions 45.
2. FIG. 5B: Apply conventional semiconductor processing techniques to etch away the semiconductor material to form via sites 59.
3. FIG. 5C: Deposit dielectric 31 that conformally coats all surfaces of the semiconductor, including the inner walls of via sites 59.
4. FIG. 5D: Provide metal filling 62 in the via sites using conventional semiconductor processing techniques, such as electroplating.
5. FIG. 5E: Remove part of the dielectric 31 on the front and back surfaces of the solar cell such that dielectric lining 61 remains.
6. FIG. 5F: Pattern the cap region 3 to create a pattern around via sites 59 in the shape of collars 21.
7. FIG. 5G: Provide top metal region 63 to make contact with the collar 21 and the metal filling 62.
8. FIG. 5H: Provide patterned back metal 53 for the back electrode.

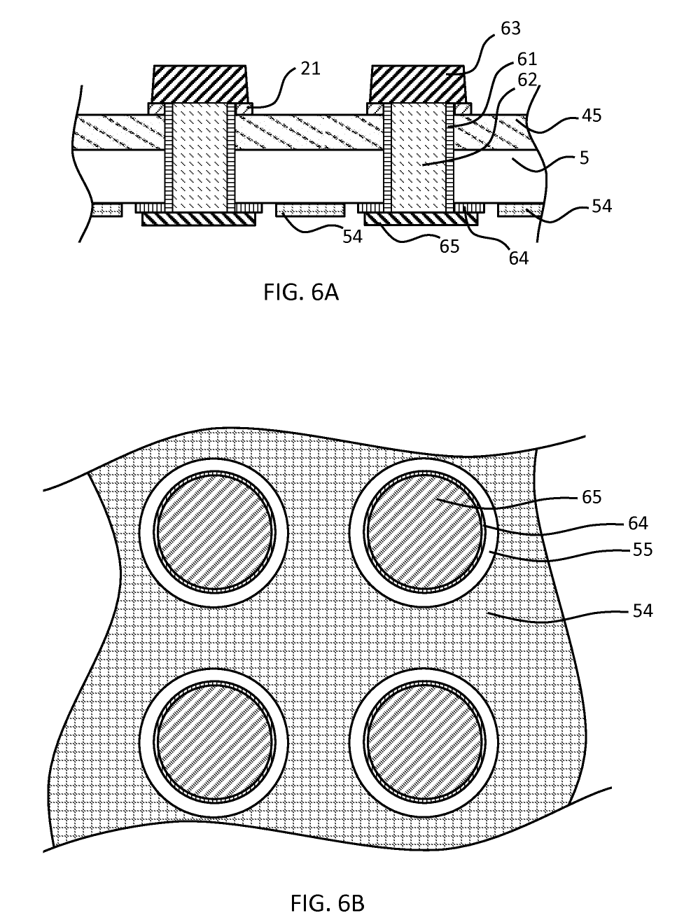

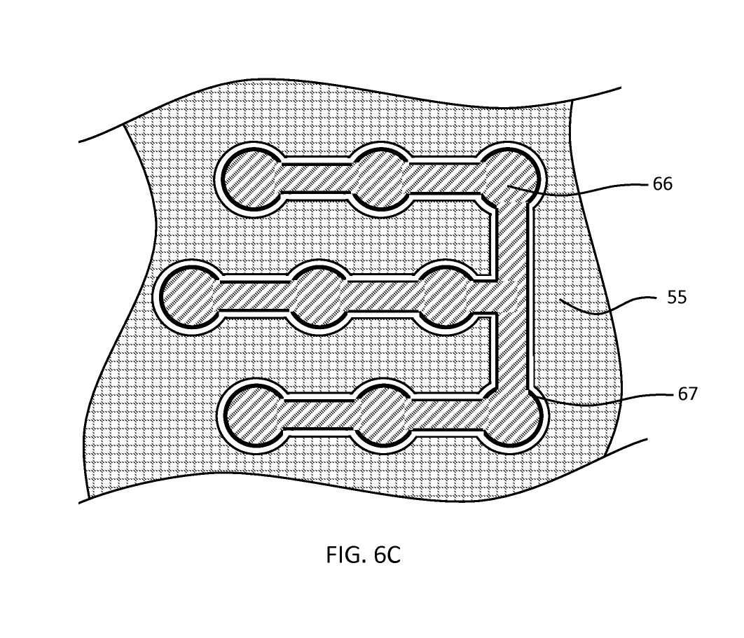

FIGS. 6A and 6B show further embodiments of the present invention, wherein an alternative back metallization is provided. Dielectric 64 is provided around the via structures 59 on the back surface of the solar cell. Thereafter, metal contact regions 65 are provided such that metal contact regions 65 make electrical contact with the associated metallic via region 62. The back-contact metal 54 is patterned to expose areas containing metal region 65 and dielectric region 64. The metallic via regions 62 typically have a cross-sectional area of about 50 microns square, whereas the metallic regions 65 have a contact area of about 100 micros square (10,000 sq. microns), which is a more suitable pad size for electrical contacts. Henceforth, the back-contact metal 54 and the metallic regions 65 are the two electrodes of the solar cell device. It is an objective of certain embodiments to provide electrode areas as defined by metallic regions 65 that are substantially larger than the cross-sectional area of the metallic regions 62.

FIG. 6B shows a top plan view of the device of FIG. 6A, including central metal contact region 65, dielectric region 64, exposed substrate 57, and back-contact metal 54.

FIG. 6C shows another embodiment of the present invention, wherein the via regions on the backside are electrically connected based on a specific backside by connection pattern. The electrode 66 is electrically isolated from the substrate via the patterned dielectric 67. The interdigitated-finger pattern of the electrodes 66 and 55 are for illustration purposes. It is to be understood that a variety of electrode patterns can be used, which may include an interdigitated-finger pattern or other patterns such as parallel electrodes that run horizontally from the electrical contacts on either sides.

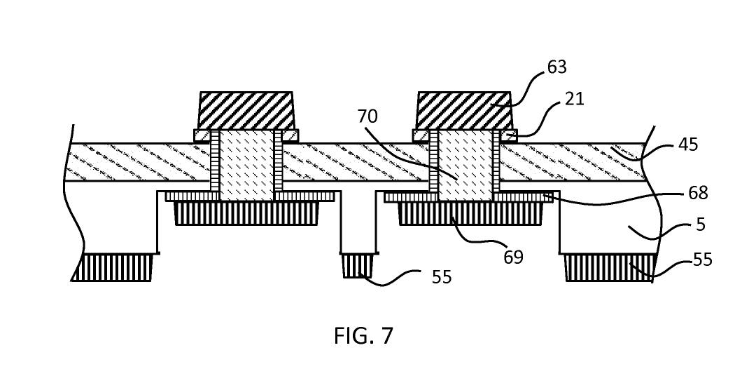

FIG. 7 shows another embodiment of the present invention, wherein the substrate is removed in selected areas from the back side to form a patterned substrate 5 that provides access to metallic vias 70 from the back side. In some embodiments the substrate can be completely removed or thinned-down uniformly. Metal electrodes 69 provide electrical contact to via structures 70 and dielectric regions 68 electrically isolate the electrodes 69 from the patterned substrate. It is an objective of certain embodiments to reduce the length, i.e., depth, of the vias 70. In some embodiments, via cap 63 can be 10 nanometers to 10 microns in thickness, and in preferred embodiments, via cap 63 is between 100 nanometers to 1 micron in thickness. In some embodiments, the diameter of via structure 70 may be 1 micron to 100 microns, and in preferred embodiments, via structure 70 has a diameter between 5 microns and 50 microns. In some embodiments, the dielectric liner thickness is between 10 nanometers and 5 microns, and in the preferred embodiment, the dielectric liner thickness is between 20 nanometers and 200 nanometers. FIG. 7 also shows dielectric collar 68, metal electrode layer 69, and metal base layer 55. The liner may be applied by deposition from a vapor or liquid phase. The dielectric liner has a sufficient thickness, is of sufficient quality, e.g., free of pinholes, and exhibits dielectric properties suitable for providing electrical isolation between the epitaxial layers, substrate, and metal layers during normal operation of the solar cell. The liner preferably forms a thin layer of substantially uniform thickness throughout the length of a through via.

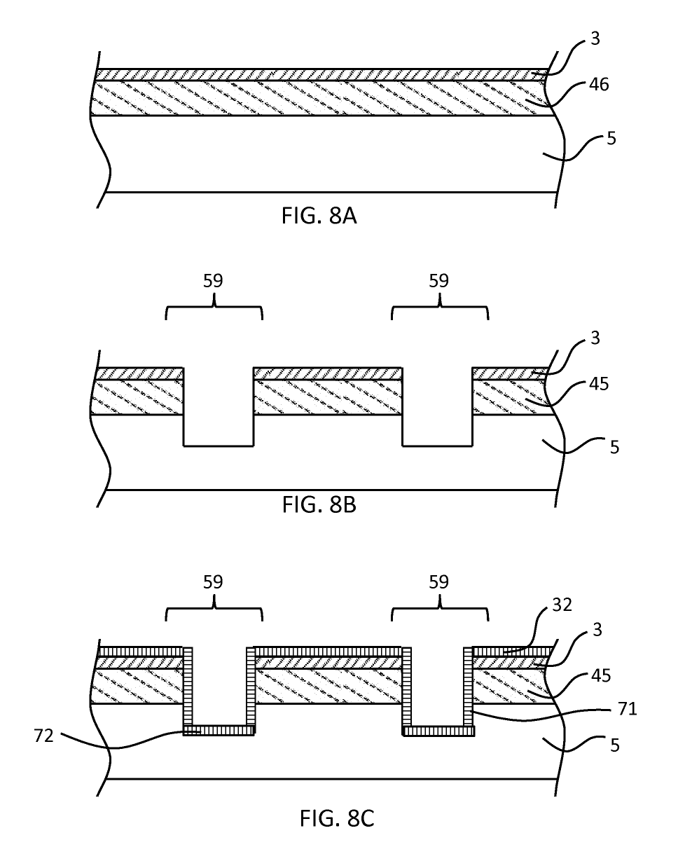

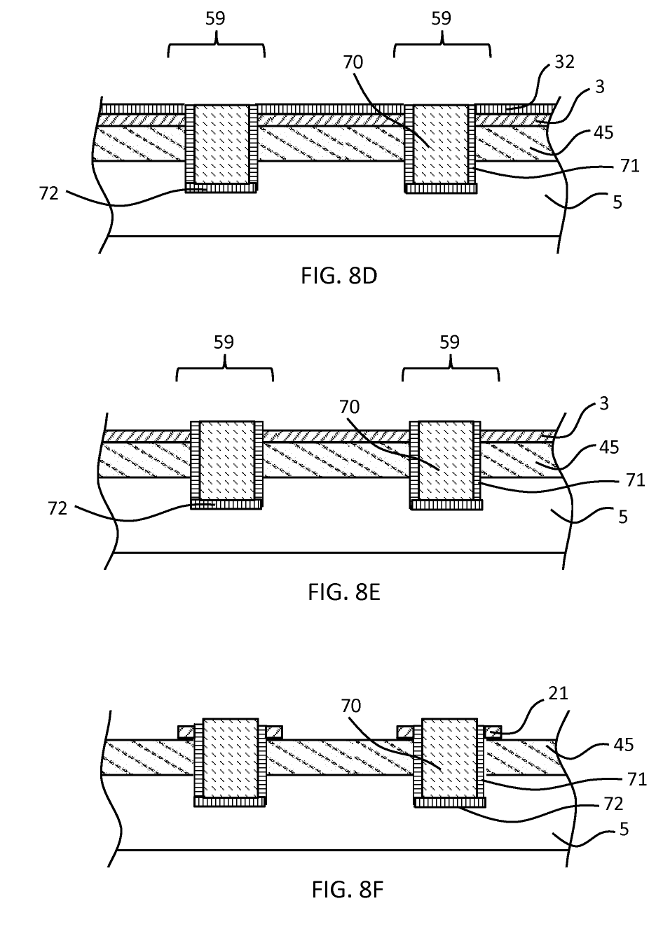

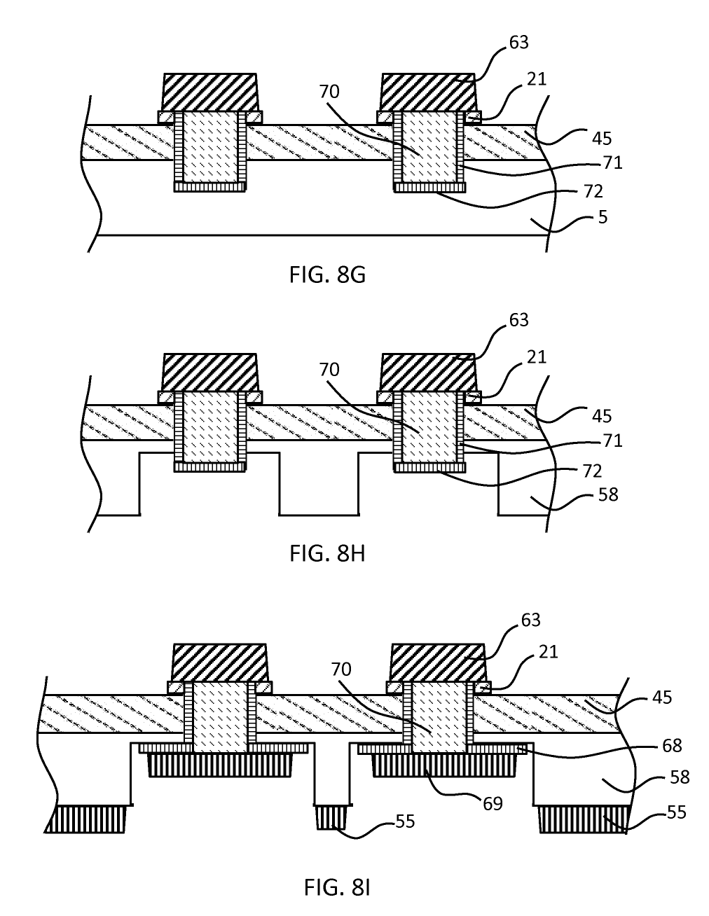

FIGS. 8A-8I illustrate process steps for making a device according to the embodiment as shown in FIG. 7. The fabrication steps provided herein are merely for illustration and are not meant to limit the scope of the invention. For example, the same structure, as depicted in FIG. 8I, may be obtained by performing a backside process, in which the via holes are etched from the backside of the device. Suitable process steps for fabricating devices provided by the present disclosure include, for example:
1. FIG. 8A: Provide a semiconductor substrate 5 with epitaxial regions 46 such that the top portion is a metallic cap region 3 and underneath is a protected and uncontaminated window front surface field (FSF) region within the epitaxial regions 45 (not shown).
2. FIG. 8B: Apply conventional semiconductor processing techniques to etch away the semiconductor material to form via sites 59.
3. FIG. 8C: Deposit dielectric 32 so that it conformally coats all exposed surfaces of the semiconductor, including the inner walls of the via sites 59 with dielectric wall lining 71 and dielectric bottom lining 72.
4. FIG. 8D: Provide metal filling 70 in the via sites 59 using conventional semiconductor processing techniques, such as electroplating.
5. FIG. 8E: Remove the dielectric 32 on the front surface of the solar cell such that dielectric lining 71 is left in the via sites 59 from dielectric 32.
6. FIG. 8F: Pattern the cap region 3 to form patterned collars 21 around each via site 59.
7. FIG. 8G: Provide top metal region 63 to make contact with the metal filling 70.
8. FIG. 8H: Pattern substrate 5 by selectively removing a portion of it according to a back-substrate pattern such that patterned substrate 5 is formed.
9. FIG. 8I: In multiple steps, remove base 72 (see FIG. 8H), add dielectric collar 68, cover the filling material 70 with a metal electrode layer 69 and provide metal base layer 55 (unconnected to layer 69) on the bottom of the substrate 5.

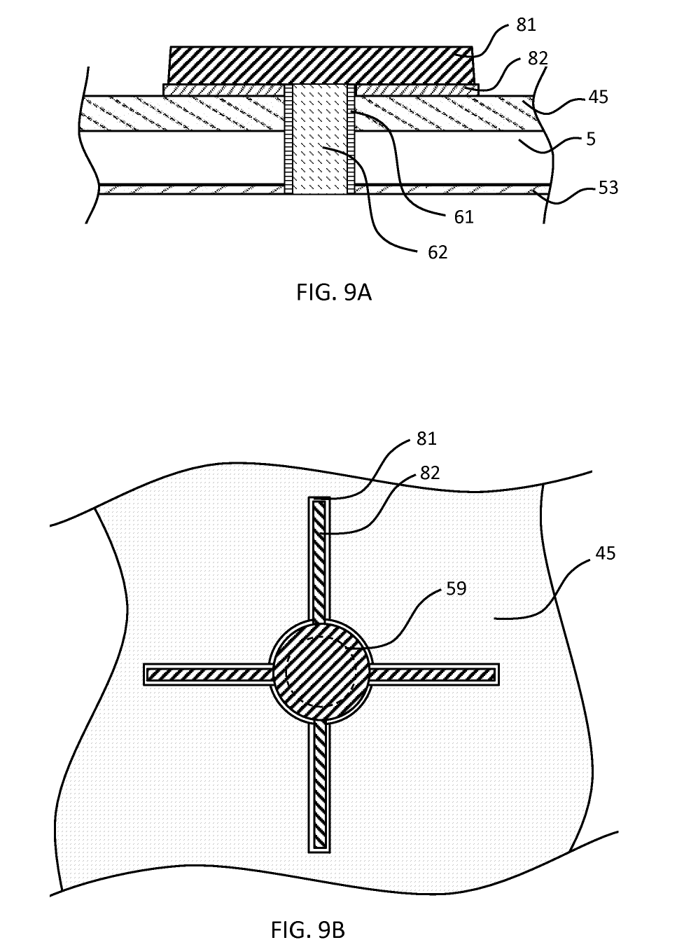

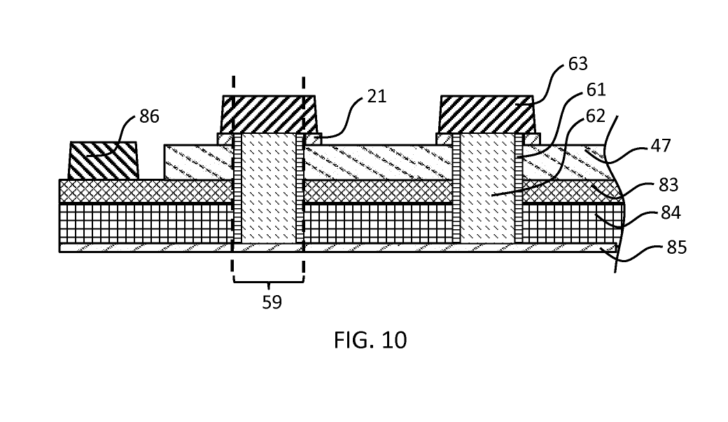

FIGS. 9A and 9B show another embodiment of the present invention, wherein metallic wires 81 are provided in the vicinity of the vias. Patterned collar region 82 underlays the metal wires 81. It is an objective of certain embodiments to reduce the number of vias in the solar cell, for a given cell size by placing them further apart from each other in order to reduce shadowing loss. The present embodiment keeps the emitter loss small enough by use of metallic wires extending out from the via regions, such that the lateral distance current flows through the lateral conduction layer is not substantially increased. Since the metallic wires can be made much shorter compared to typical prior art gridlines, the resistive losses associated with them will be minimal The metallic wires can follow a variety of patterns depending on the multi junction solar cell design requirements. Since the metallic wires are typically short, it may not be necessary to use silver or other high conductive metals to make the metallic wires. Hence the present embodiment enables multi junction solar cells without silver metallization.

FIG. 9A shows epitaxial region 45 overlying substrate 5 and back surface metal 53. Through vias extend from patterned collar region 82 through epitaxial region 46, substrate 5, and back metal 53. The through vias are lined with an insulating material 61 and filled with electrically conductive material 62. Metal wires 81 overly patterned collar region 82 and the through via and make electrical contact with conductive material 62. FIG. 9B is a plan view of the upper surface of the device shown in FIG. 9A, and includes metal wires 81 overlying patterned collar region 82 disposed over through via 59 and epitaxial region 45.

FIG. 10 shows another embodiment of the present invention, wherein the substrate 84 is made of semi-insulating semiconductor material. A lower conduction layer 83 is provided between the substrate 84 and the patterned multi junction epitaxial region 47. The through-vias 59 extend from the patterned cap region 21, through junction region 47, lower conduction region 83 and the semi-insulating substrate 84. Back metal 85 covers the entire back surface of the substrate 84. Metal contacts 86 are provided on exposed areas of the lower conduction region 83. In a preferred embodiment, the sidewall insulating layer 61 extends along the entire length of the via site sidewalls. However, since the substrate 84 in this case is semi-insulating, the insulating layer 61 may be omitted, or partially omitted, along the sidewalls of a via site 59 where the via site passes through the substrate. It is an objective of certain embodiments to eliminate patterning of the backside of the solar cells. In some embodiments, a via cap 63 can be 10 nanometers to 10 microns in thickness, and in preferred embodiments, the via cap 63 is between 100 nanometers to 1 micron in thickness. In some embodiments, the diameter of a via structure 62 may be 1 microns to 100 microns, and in preferred embodiments, the via structure 62 diameter is between 5 microns and 50 microns. In some embodiments, the dielectric liner 61 thickness is between 10 nanometers and 5 microns, and in the preferred embodiment, the dielectric liner 61 thickness is between 20 nanometers and 200 nanometers. Finally, in some embodiments, the lower conduction region, 83, is 100 nanometers to 10 microns wide, while in preferred embodiments, this region is 1 microns to 5 microns wide.

The designs and methods provided by the present disclosure improve the performance of solar cells compared to those of the prior art by reducing shadowing loss, emitter loss, and grid loss. For example, in certain embodiments, solar cells provided by the present disclosure exhibit a shadowing loss less than 5%, an emitter loss is less than 2%, and a grid loss is less than 0.1%. In certain embodiments, the shadowing loss is less than 4%, less than 2%, and in certain embodiments less than 1%. In certain embodiments, the emitter loss is less than 2%, less than 1%, and in certain embodiments less than 0.5%. In certain embodiments, the grid loss is less than 0.1%, less than 0.05%, and in certain embodiments less than 0.025%.

It is to be understood that other embodiments may be utilized and structural or logical changes may be made without departing from the scope of the present invention. Therefore the foregoing description is not to be taken in a limiting sense. The scope of the present invention is defined by the appended claims and their equivalents.

What is claimed is:

1. A multi junction solar cell comprising:
an electrically conductive semiconductor substrate with at least one multi junction solar cell element formed in an epitaxial region grown thereon;
a cap region formed on top of the epitaxial region;
though-wafer vias that extend from the cap region to a back surface of the substrate;
the cap region being shaped according to a cap pattern comprising collars around the through-wafer vias;
conductive metal within the through-wafer vias and electrically connected to the collars;
an electrically insulating liner on the inner walls of the through-wafer vias insulating the substrate and the epitaxial region from the conductive metal inside the through-wafer vias that connect with the cap region; and
a back metal in ohmic contact with the back surface of the substrate, the back metal being electrically connected with the conductive metal within the through-wafer vias, and wherein the back metal is patterned with a back metal pattern.

2. The multi junction solar cell of claim 1, further comprising:
a patterned dielectric layer on the back surface of the substrate;
metal regions comprising contact pads on the patterned dielectric layer, wherein the contact pads are in direct electrical contact with the conductive metal inside the through-wafer vias, the contact pads are not directly electrically connected to the semiconductor substrate or to the back metal.

3. The multi junction solar cell of claim 2, wherein the contact pads are patterned such that multiple contact pads are electrically connected together, thereby electrically tying together multiple metal vias.

4. The multi junction solar cell of claim 2, wherein the back surface of the substrate comprises recesses comprising metal electrodes electrically connected to the through-wafer vias.

5. The multi junction solar cell of claim 1, wherein the back surface of the substrate comprises recesses comprising metal electrodes electrically connected to the through-wafer vias.

6. The multi junction solar cell of claim 1, comprising metal gridlines interconnect multiple cap regions.

7. The multi junction solar cell of claim 1, comprising top metal and gridlines electrically connected to the cap region, wherein the top metal and the gridlines are characterized by a sheet resistance less than 5 ohms/square.

8. The multi junction solar cell of claim 1, wherein the multi junction solar cell is characterized by a shadowing loss less than 5%, an emitter loss less than 2%, and a grid loss less than 0.1%.

9. A multi junction solar cell comprising:
a semi-insulating semiconductor substrate having a top surface and a back surface;
an epitaxial region overlying the top surface of the substrate;
an electrically conductive semiconductor region between the top surface of the substrate and the epitaxial region;
at least one multi junction solar cell element formed in the epitaxial region;
a cap region formed overlying the epitaxial region;
though-wafer vias that extend from the cap region to the back surface of the substrate;
the cap region being shaped according to a cap pattern comprising a collar around each of the through-wafer vias;
conductive metal within each of the through-wafer vias and electrically connected to the respective collar;
an electrically insulating liner on the inner walls of each of the through-wafer vias insulating the conductive metal within each of the through-wafer vias from at least the epitaxial region and the electrically conductive semiconductor region; and
a back metal in electrical contact with the conductive metal in each of the through-wafer vias.

10. The multi junction solar cell of claim 9, comprising metal gridlines interconnecting multiple cap regions.

11. The multi junction solar cell of claim 9, comprising top metal and gridlines electrically connected to the cap region, wherein the top metal and the gridlines are characterized by a sheet resistance from 0.01 ohms/square to 1 ohm/square.

12. The multi junction solar cell of claim 9, wherein the multi junction solar cell is characterized by a shadowing loss less than 5%, an emitter loss less than 2%, and a grid loss less than 0.1%.

13. A multi junction solar cell, comprising:
a substrate comprising a lower surface and an upper surface, wherein the upper surface faces the direction of incident radiation;
an epitaxial region overlying the upper surface of the substrate, wherein the epitaxial region comprises at least one sub-cell and an upper epitaxial surface;
a back metal contact disposed on the lower surface of the substrate; and
a plurality of through-vias extending from an annular cap region overlying the upper epitaxial surface to the back metal contact, wherein each of the plurality of through-vias comprises a dielectric liner on the walls of the through-via and an electrically conductive material within a central portion of the through-via;
wherein the annular cap region, the electrically conductive material within the central portion of a through-via, and the back metal contact are electrically connected.

14. The multi junction solar cell of claim 13, wherein the center-to-center distance between adjacent through vias is from 100 microns to 200 microns.

15. The multi junction solar cell of claim 13, wherein the multi junction solar cell is characterized by a shadowing loss less than 5%, an emitter loss less than 2%, and a grid loss less than 0.1%.

16. The multi junction solar cell of claim 13, comprising gridlines disposed on the lower surface of the substrate.

17. The multi junction solar cell of claim 16, wherein the gridlines electrically interconnect multiple through-vias.

18. The multi junction solar cell of claim 13, wherein through-vias are characterized by a resistance of less than 0.01 ohms for each via.

19. The multi junction solar cell of claim 13, comprising top metal and gridlines electrically connected to the cap region, wherein the top metal and the gridlines are characterized by a sheet resistance less than 5 ohms/square.

20. The multi junction solar cell of claim 13, comprising top metal and gridlines electrically connected to the cap region, wherein the top metal and the gridlines are characterized by a sheet resistance from 0.01 ohms/square to 1 ohm/square.
